(19) United States
(12) Patent Application Publication
(10) Pub. No.: US 2004/0171258 A1
(43) Pub. Date: Sep. 2, 2004

(54) Method for fabricating a merged semiconductor device

(76) Inventor: Nam-kyu Park, Cheongju-shi (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/785,777

(22) Filed: Feb. 24, 2004

(30) Foreign Application Priority Data
Feb. 27, 2003 (KR) 2003-12402

(51) Int. Cl. H01L 21/302; H01L 21/461

(52) U.S. Cl. 438/689

(57) ABSTRACT

The present invention discloses a method for fabricating a merged semiconductor device, the merged semiconductor device including a logic region, an I/O region and a high voltage region, which simplifies process steps by making an oxide film have different thicknesses for each region and conducting a threshold voltage control ion implantation process simultaneously on each of the regions, with photographic and etching processes being omitted. The method comprises the steps of: forming an oxide film on a semiconductor substrate; etching the oxide films of a high voltage N-well forming region and of a key pattern region so as to have an initial thickness and then performing an ion implantation process; etching the oxide film of a high voltage P-well forming region of the resultant material so as to have a second thickness and then performing an ion implantation process; conducting thermal diffusion to the resultant material, which the ion implantation process is performed to, to diffuse implanted ions; forming a N-drift region and a P-drift region in the high voltage region; and performing a channel ion implantation process using the oxide films of the first thickness and the second thickness as a mask without any additional photographic process.

### BACKGROUND OF THE INVENTION

1. Field of the Invention

The present invention relates to a merged semiconductor device, and more particularly, to a method for fabricating a merged semiconductor device, the merged semiconductor device including a logic region, an I/O region and a high voltage region, which simplifies the process by making an oxide film with different thicknesses for each region and conducting a threshold voltage control ion implantation process simultaneously on each of the regions, with the photographic and etching processes being omitted.

2. Description of the Related Art

In the conventional art, where a high voltage device having a DDD structure, a logic device performing a low voltage driving and an I/O device are implemented together, which leads to a deterioration of the characteristics of the logic device.

The conventional problem will be explained in more detail.

To form the DDD structure of the high voltage device, a diffusion process is performed for a long time period under high temperatures. This affects the logic device and the I/O region. Thus, in order to prevent the influence of the diffusion process on the logic and I/O regions, it is necessary to add a photoresist coating and etching processes for blocking the logic and I/O regions. This results in an increase in the number of steps, which increases fabrication costs.

The above-stated problem of the method for fabricating a merged semiconductor device according to the conventional art will be described with reference to FIG. 1.

FIGS. 1a to 1f are cross sectional views of processes showing a method for fabricating a merged semiconductor device according to the conventional art.

First, an oxide film 101 is formed on a silicon substrate 100 at a thickness of 100 to 200 Å by a thermal oxidation or high-pressure, low temperature decomposition (HLD). Then, a photoresist film 102 is coated for forming a key pattern for the isolation between devices, and then patterned to open a key pattern region. Continuously, a predetermined trench 103 is formed in the key pattern region by conducting an etching process.

Then, as shown in FIG. 1b, a photoresist film 104 is coated, then a logic region (A) and a high voltage N-well (hereinafter, referred to as HNW) region of a high voltage region (B) are opened, and then an implantation process is performed on the HNW regions. At this time, the logic region (A) may not form a deep junction by being blocked by a photoresist film according to a driving voltage of the logic region (A).

Continually, as shown in FIG. 1c, a photoresist film 105 is coated, then a high voltage P-well (hereinafter, referred to as a HPW region) of the high voltage region (B) is opened, and then an implantation process is performed.

As shown in FIG. 1d, to the resultant material, which the implantation process is performed, a diffusion process is performed to activate doped ions so that the HNW region and the HPW region become a deep junction.

FIG. 1e is a view in which some parts of the resultant material of FIG. 1d are shifted. As shown therein, to form a N-drift region in the HPW region of the high voltage region (B), a photoresist pattern 106 is formed and then an ion implantation process is conducted. As shown in FIG. 1f, to form a P-drift region in the HNW region of the high voltage region (B), a photoresist pattern 107 is formed and then an ion implantation process is conducted.

As shown in FIG. 1g, to the resultant material, a diffusion process is conducted to diffuse the N-drift region and the P-drift region.

Then, though not shown, a photographic process is conducted so that each of NMOS and PMOS regions of the high voltage region can be opened in order, and a channel ion implantation process is conducted to control the threshold voltage of each region.

As described above, the conventional art requires an additional photographic and etching process of two steps to control the threshold voltage of each region. A detailed reason thereof will be explained as follows.

A PMOS transistor and a NMOS transistor each have a surface channel. The work function differences (=φₘₛ) of metal semiconductor are φₘₛ=−{Eg/2q+φ_{fp}} of N+ polysilicon over a n-type silicon and φₘₛ={Eg/2q−φ_{fn}} of P+ polysilicon over a n-type silicon. Here, Eg represents the energy band gap, q represents the unit charge, and φ_{fp} (φ_{fn}) represents the potential difference between the Fermi level of an intrinsic semiconductor and the Fermi level of an impurity semiconductor.

Consequently, the threshold voltage of the NMOS transistor and the threshold voltage of the PMOS transistor are obtained by the following formula 1:

NMOS(V_{TH})=φₘₛ−2φ_{fp}−|Q_{d}/C_{OX}|=−Eg/2q++φ_{fp}+|Q_{d}/C_{OX}|

PMOS(V_{TH})=φₘₛ−2φ_{fn}−|Q_{d}/C_{OX}|=Eg/2q−φ_{fn}−|Q_{d}/C_{OX}| Formula 1

Subsequently, according to the above formula, a difference in threshold voltage between the NMOS transistor and the PMOS transistor is generated. In other words, the threshold voltage of the NMOS transistor becomes much higher than that of the PMOS transistor. Due to this difference in threshold voltage between the two regions, the concentrations of BF2 ions implanted into the regions for controlling the threshold voltage of each region are made different from each other. In order to carry out ion implantation process at difference concentrations, an additional photographic process of two steps is conducted to each region and then an ion implantation process is conducted thereto. As a result, there is an increase in the number of steps in the photographic and etching process.

Besides, in the method for fabricating a merged semiconductor device according to the conventional art, the photographic and etching processes are conducted for forming a key pattern for the isolation of devices.

However, in the semiconductor device fabrication process, as the number of steps of the photographic process increases, the production cost alsoincreases, and an etching process accompanies the photographic process. This leads to a failure of the devices and, as a result, lowers the reliability of the devices.

### SUMMARY OF THE INVENTION

The present invention is designed in consideration of the problems of the prior art, and therefore it is an object of the present invention to provide a method for fabricating a merged semiconductor device, the merged semiconductor device including a logic region, an I/O region and a high voltage region, which simplifies process steps by depositing an oxide film with a predetermined thickness, forming junction regions while making the oxide film have a different thickness for each of the regions and conducting a threshold voltage control ion implantation process without any additional photographic or etching processes.

To achieve the above object, there is provided a method for fabricating a merged semiconductor device, the merged semiconductor device provided with logic and I/O regions and a high voltage region, comprising the steps of: forming an oxide film on a semiconductor substrate; etching the oxide films of a high voltage N-well forming region and of a key pattern region so as to have a inital thickness and then performing an ion implantation process; etching the oxide film of a high voltage P-well forming region of the resultant material so as to have a second thickness and then performing an ion implantation process; conducting thermal diffusion to the resultant material, which the ion implantation is performed to, to diffuse implanted ions; forming a N-drift region and a P-drift region in the high voltage region; and performing a channel ion implantation process using the oxide films of the first thickness and the second thickness as a mask without any additional photographic process.

In the method for fabricating a merged semiconductor device of the present invention, during the etching process of the oxide film of the high voltage P-well forming region, the oxide film in the key pattern region and parts of the silicon substrate are etched using an etching selection ratio so as to form a trench. Accordingly, the number of process steps can be reduced since there is no need to carry out any additional photographic process for forming a key pattern.

In addition, in the method for fabricating a merged semiconductor device, an initial oxide film is formed at a large thickness on the semiconductor substrate, then the oxide films of the NMOS region and of the PMOS region are made to have different thicknesses and then channel ion implantation process is carried out, whereby each of the regions becomes different in the concentration of ions implanted into the silicon substrate according to different thicknesses of the oxide films, thus the threshold voltage control by a single ion implantation is enabled without performing any additional photographic or etching process.

### BRIEF DESCRIPTION OF THE DRAWINGS

Other objects and aspects of the present invention will become apparent from the following description of embodiments with reference to the accompanying drawings in which:

FIGS. 1a to 1f are cross sectional views of processes showing a method for fabricating a merged semiconductor device according to the conventional art; and

FIGS. 2a to 2g are cross sectional views of processes showing a method for fabricating a merged semiconductor device according to the present invention.

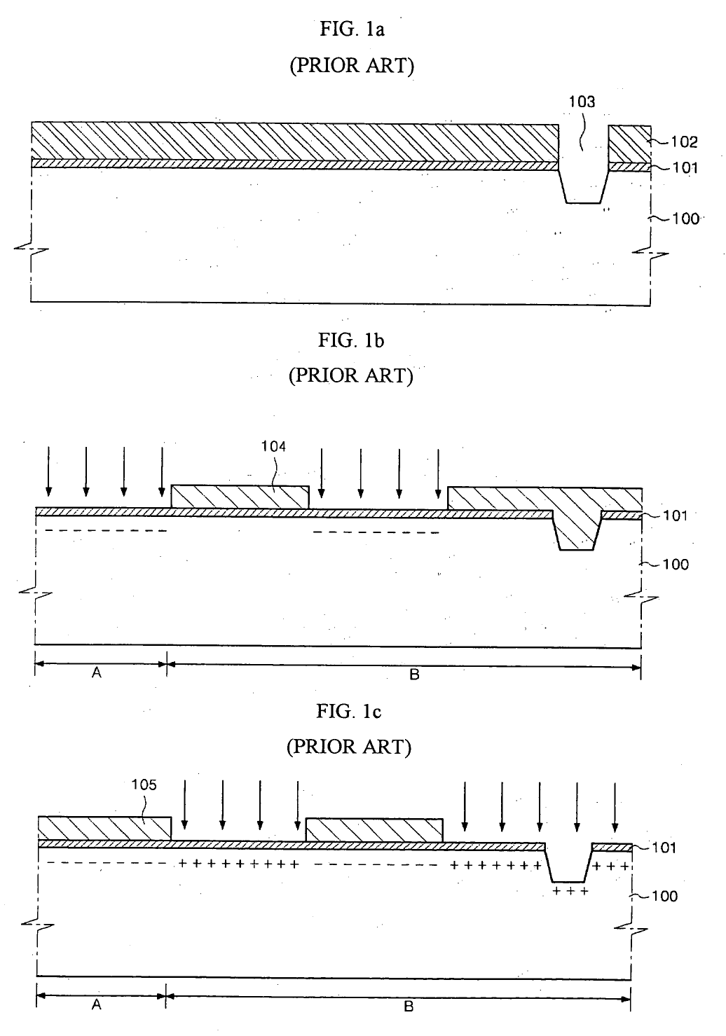

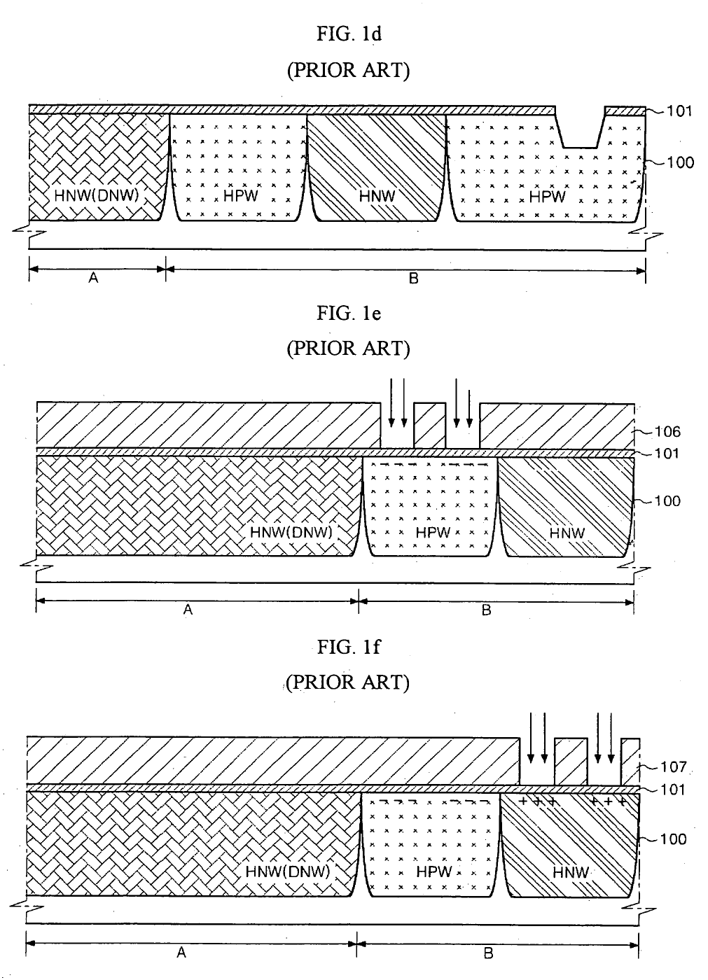

### DESCRIPTION OF THE PREFERRED EMBODIMENT

Hereinafter, a preferred embodiment of the present invention will be described in more detail referring to the drawings. In addition, the following embodiment is for illustration only, not intended to limit the scope of the invention.

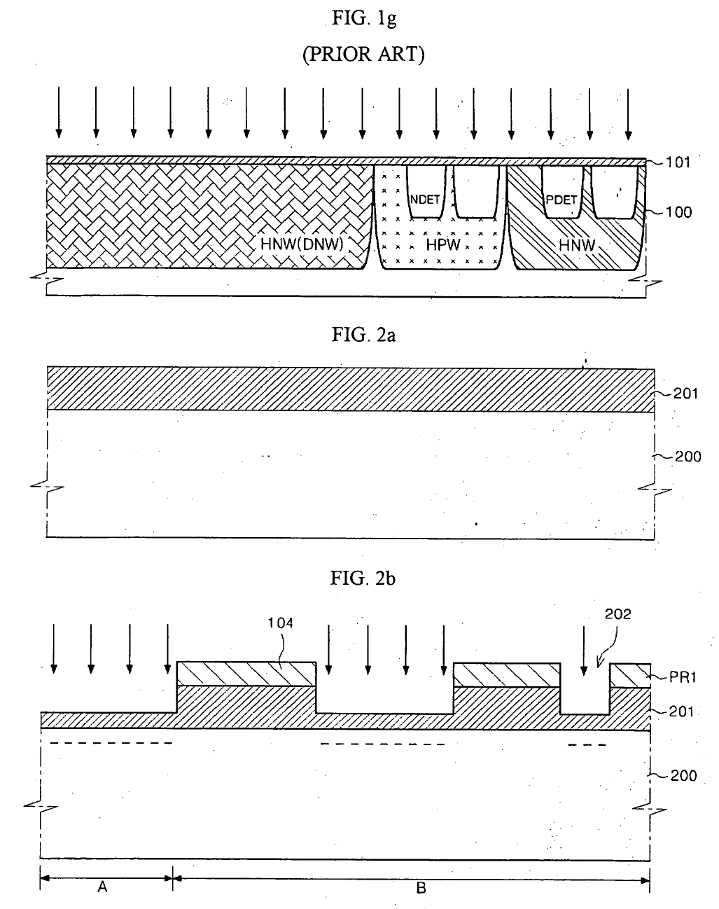

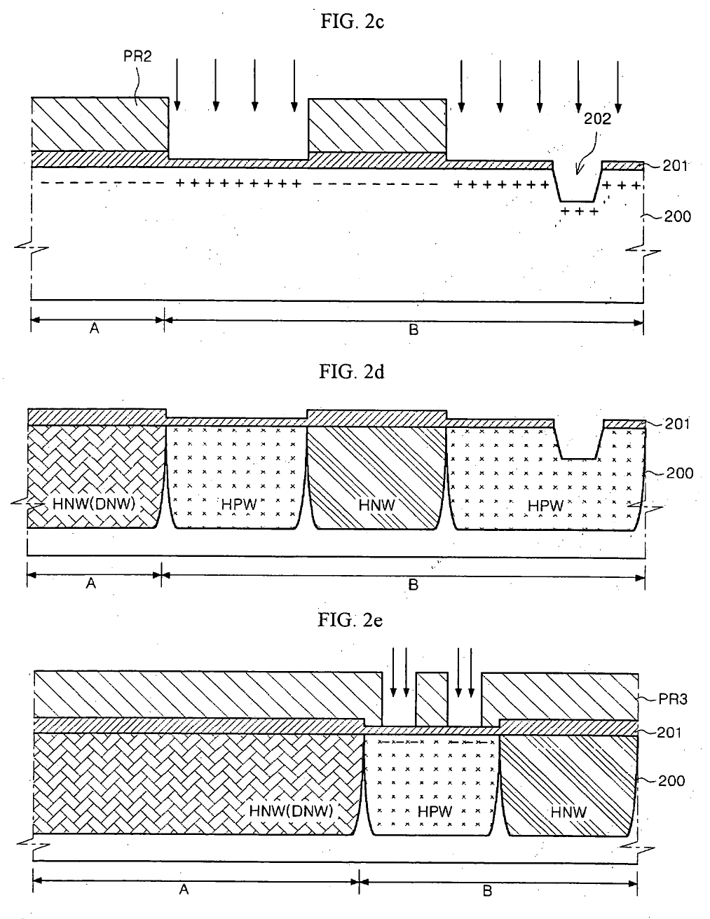

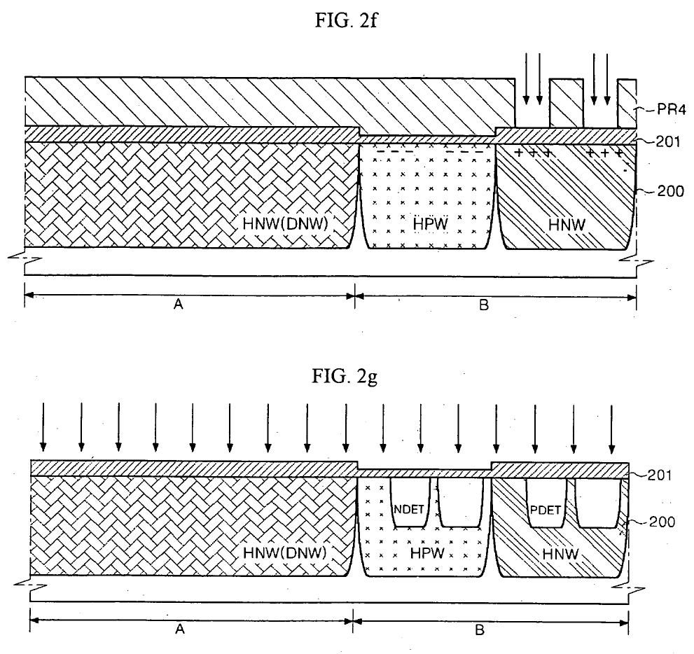

FIGS. 2a to 2g are cross sectional views of processes showing a method for fabricating a merged semiconductor device according to the present invention.

First, an oxide film 201 is formed on a semiconductor substrate 200 at a thickness of 120 nm by a thermal oxidation or high pressure low temperature decomposition (HLD). At this time, the present invention is characterized in that a subsequent etching process is conducted on the oxide film to reduce a number of steps of the photographic process for a threshold voltage control, though, in the conventional art, the oxide film is thinly deposited at 10 to 20 nm. Thus, it is preferred to deposit the oxide film thickly.

Next, as shown in FIG. 2b, a photoresist film (PR1) is coated on the semiconductor device 200, and then patterned so that a logic region, an I/O region, a high voltage N-well (hereinafter, referred to as HNW) region of a high voltage region (V) and a key pattern region 202 can be opened. At this time, the logic region may not be opened if it does not require a deep junction according to a driving voltage.

Then, the oxide film of the HNW region is etched using the photoresist pattern (PR1) so that an oxide film with a 200 Å thickness remains. At this time, the oxide film 201 of the key pattern region 202 is etched simultaneously. Then, using the photoresist pattern 202 and the oxide film 201 as a blocking film, an implantation using phosphorous (P) ions is conducted on the HNW region, and then the photoresist film is removed.

Continually, as shown in FIG. 2c, a photoresist film (PR2) is coated and then patterned so that the HPW region including the key pattern region can be opened. And, the oxide film 201 of the HPW region is etched at 110 nm using the photoresist pattern (PR2), and an ion implantation process using boron ions is conducted. At this time, the silicon substrate of the key pattern region 202 is etched at an etching selection ratio of oxide film to silicon substrate, resulting in a shallow trench isolation (STI) in the key pattern region.

Continually, as shown in FIG. 2d, the resultant material, which the ion implantation process is conducted to, is heat-treated for a long period of time under high temperatures, thereby forming a deep junction region by diffusion. For example, thermal diffusion is sufficiently conducted for over 500 minutes under a temperature of 1200° C. to form a deep junction.

FIG. 2e is a view wherein some parts of the resultant material of FIG. 2d are shifted. After the formation of the deep junction, as shown therein, a predetermined photoresist film (PR3) is coated, then patterned so that a drift region of the HPW region of the high voltage region can be opened, and then an ion implantation process is conducted. And, as shown in FIG. 2f, the photoresist film (PR3) is removed, then a predetermined phothoresist film (Pr4) is coated and then patterned so that the HNW region of the high voltage region can be opened, and then ion implantation process is conducted.

As shown in FIG. 2g, to the resultant material, to which the ion implantation process is conducted to, annealing is conducted to thus form a N-drift region and a P-drift region.

And, without performing a photographic process on the resultant material, a channel ion implantation process for a threshold voltage control is performed. At this time, the oxide film of each of the regions has a different thickness, so it is possible to conduct a different channel ion implantation process to each of the regions even if any particular photoresist film pattern process is not conducted.

According to the present invention, since the HNW region is formed with an oxide film of a 200 Å thickness and the HPW region is formed with an oxide film of a 100 Å thickness, it is possible to satisfy a threshold voltage required by each of the regions even though a BF₂ implantation was conducted using a low energy without any particular photographic process. At this time, the threshold voltages of the logic and I/O regions are shifted by no more than 0.5V, thus it is not a major concern. As a result, only an oxide film etching process is conducted using the photographic process conducted for the ion implantation process for forming a deep junction, and the threshold voltage of each of the regions is controlled without any additional photographic and etching processes, thereby reducing the process costs in accordance with reduction of the number of process steps.

As seen from above, the present invention can simplify process steps and reduce the process costs by omitting an additional photographic process, which is conducted for controlling a threshold voltage for each of the regions required for implementing a high voltage transistor. As a result, the present invention is quite advantageous from the viewpoint of throughput.

Further, the present invention has a merit in that the reliability of the device can be improved by preventing a defective pattern of the device in accordance with an additionally photographic and etching process.

What is claimed is:

1. A method for fabricating a merged semiconductor device, the merged semiconductor device provided with logic and I/O regions and a high voltage region, comprising the steps of:
forming an oxide film on a semiconductor substrate;
etching the oxide films of a high voltage N-well forming region and of a key pattern region so as to have a initial thickness and then performing an ion implantation process;
etching the oxide film of a high voltage P-well forming region of the resultant material so as to have a second thickness and then performing an ion implantation process;
conducting thermal diffusion to the resultant material, which the ion implantation process is performed to, to diffuse implanted ions;
forming a N-drift region and a P-drift region in the high voltage region; and
performing a channel ion implantation process using the oxide films of the first thickness and the second thickness as a mask without any additional photographic process.

2. The method of claim 1, wherein, in the step of etching the oxide film of the high voltage P-well forming region, the oxide film of the key pattern region and the silicon substrate are partially etched to form a trench.

3. The method of claim 1, wherein the oxide film initially formed on the semiconductor substrate is formed at 100 to 200 nm.

4. The method of claim 1, wherein the oxide film of the intital thickness is 200 Å.

5. The method of claim 1, wherein the oxide film of the second thickness is 100 Å.

6. The method of claim 1, wherein the channel ion implantation process is performed using BF₂ ions.
